(19) United States
(12) Patent Application Publication
(10) Pub. No.: US 2022/0384657 A1
(43) Pub. Date: Dec. 1, 2022

(54) TRANSISTOR, ELECTRONIC DEVICE, AND METHOD FOR MANUFACTURING TRANSISTOR

(71) Applicants: NIKON CORPORATION, Tokyo (JP); TORAY ENGINEERING CO., LTD., Tokyo (JP)

(72) Inventors: Makoto NAKAZUMI, Yamato-shi (JP); Tsukasa KISHIUME, Kawasaki-shi (JP); Masaki MORI, Otsu-shi (JP); Takayoshi FUJIMOTO, Otsu-shi (JP)

(73) Assignees: NIKON CORPORATION, Tokyo (JP); TORAY ENGINEERING CO., LTD., Tokyo (JP)

(21) Appl. No.: 17/884,276

(22) Filed: Aug. 9, 2022

Related U.S. Application Data
(63) Continuation of application No. PCT/JP2021/005865, filed on Feb. 17, 2021.

(30) Foreign Application Priority Data
Feb. 20, 2020 (JP) 2020-027134

(51) Int. Cl. H01L 29/786; H01L 29/66; H01L 21/02

(52) U.S. Cl. CPC H01L 29/7869; H01L 29/66742; H01L 21/02274; H01L 21/02164; H01L 21/02167

(57) ABSTRACT

What is provided is a transistor including a gate electrode, a gate insulating film, a semiconductor film, a source electrode, and a drain electrode, in which the gate insulating film is a laminated film in which a SiOₓ film and a SiC_{y}N_{z} film are alternately formed, the total number of films constituting the laminated film is 3 or more and 18 or less, and the thickness of each film constituting the laminated film is 25 nm or more and 150 nm or less.

### TECHNICAL FIELD

The present invention relates to a transistor, an electronic device, and a method for manufacturing a transistor.

Priority is claimed on Japanese Patent Application No. 2020-027134, filed in Japan on Feb. 20, 2020, the content of which is incorporated herein by reference.

### BACKGROUND ART

Thin film transistors (TFTs) are widely used in liquid crystal display devices, organic electroluminescence (EL) display devices, and the like.

Oxide semiconductors are attracting attention as semiconductor film materials for thin film transistors. Among them, thin film transistors using amorphous oxide semiconductors such as In—Ga—Zn—O (IGZO) are attracting attention.

Moreover, for example, a gate insulating layer of the thin film transistor is formed by a chemical vapor deposition (CVD) method as described in Patent Document 1. Recently, there is a demand for a display device to have a higher performance, and a thin film transistor having a high insulation performance and high reliability is required.

### CITATION LIST

### Patent Document

### [Patent Document 1]

Japanese Unexamined Patent Application, First Publication No. 2017-107952

### SUMMARY OF INVENTION

According to an aspect of the present invention, there is provided is a thin film transistor including a gate electrode, a gate insulating film, a semiconductor film, a source electrode, and a drain electrode, in which the gate insulating film is a laminated film in which a SiOₓ film and a SiC_{y}N_{z} film are alternately formed, the total number of films constituting the laminated film is 3 or more and 18 or less, and the thickness of each film constituting the laminated film is 25 nm or more and 150 nm or less.

### BRIEF DESCRIPTION OF DRAWINGS

FIG. 1 is a schematic cross-sectional view of an example of a thin film transistor according to the present embodiment.

FIG. 2 is a diagram showing transistor characteristics of the thin film transistor manufactured in Example 1.

FIG. 3 is a diagram showing transistor characteristics of the thin film transistor manufactured in Example 2.

FIG. 4 is a diagram showing transistor characteristics of the thin film transistor manufactured in Example 3.

FIG. 5 is a diagram showing transistor characteristics of the thin film transistor manufactured in Example 4.

FIG. 6 is a diagram showing transistor characteristics of the thin film transistor manufactured in Comparative Example 1.

FIG. 7 is a diagram showing transistor characteristics of the thin film transistor manufactured in Comparative Example 2.

### DESCRIPTION OF EMBODIMENTS

<Thin Film Transistor>

The present embodiment is a thin film transistor including a gate electrode, a gate insulating film, a semiconductor film, a source electrode, and a drain electrode.

In the present embodiment, the gate insulating film is a laminated film in which a SiOₓ film and a SiC_{y}N_{z} film are alternately laminated.

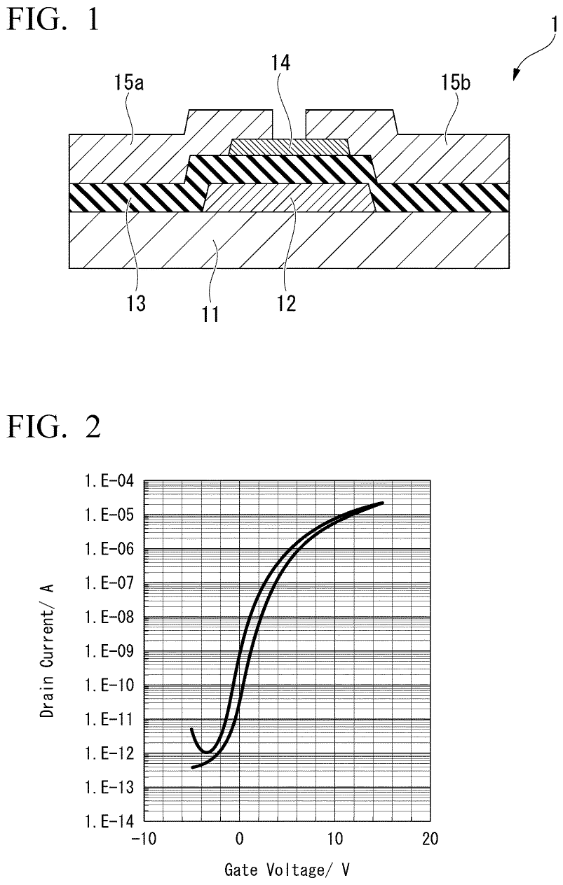

A thin film transistor 1 shown in FIG. 1 is a bottom-gate type thin film transistor formed on a surface of a substrate 11. The thin film transistor 1 includes a gate electrode 12, a gate insulating film 13, a semiconductor film 14, a source electrode 15a, and a drain electrode 15b.

Hereinafter, each configuration thereof will be described.

<<Substrate>>

Examples of a material of the substrate 11 include metals, crystalline materials, amorphous materials, conductors, semiconductors, insulators, fibers, glass, ceramics, zeolites, plastics, and thermosetting and thermoplastic materials. In addition, the substrate 11 may be an optical element, a coated substrate, a film, or the like.

Examples of the crystalline material include a single crystalline material, a polycrystalline material, or a partially crystalline material.

Examples of the thermoplastic material include polyacrylate, polycarbonate, polyurethane, polystyrene, cellulose polymer, polyolefin, polyamide, polyimide, polyester, polyphenylene, polyethylene, polyethylene terephthalate, polyethylene naphthalate, polypropylene, ethylene vinyl copolymer, and polyvinyl chloride. These materials may be doped.

In the present embodiment, polyimide or polyethylene naphthalate is preferable as the material of the substrate 11.

The softening point of the polyimide is 290° C. The softening point of polyethylene naphthalate is 120° C.

In the present embodiment, the substrate 11 is preferably a flexible substrate.

Here, the “flexibility” refers to a property that allows the substrate 11 to bend even when a force roughly equal to its own weight is applied to the substrate 11 without disconnecting or breaking.

In addition, the property of allowing the substrate 11 to be curved by the force roughly equal to its own weight is also included in the concept of flexibility. In the present embodiment, the flexibility of the substrate 11 varies depending on the material, size, thickness, environment such as temperature, and the like of the substrate 11.

As the flexible substrate 11, a substrate made of a resin material is preferable.

As the substrate 11, a long substrate can be used. Further, in the present embodiment, the substrate 11 may be formed in a long shape by connecting a plurality of unit substrates.

<<Gate Electrode>>

The gate electrode 12 is formed on the surface of the substrate 11. The gate electrode 12 has conductivity. A material constituting the gate electrode 12 is not particularly limited. In the present embodiment, examples of the material of the gate electrode 12 include Al, Mo, Cu, Ti, Au, and Ni.

The gate electrode 12 may be a laminate in which these materials are used alone or a laminate in which two or more materials are used in combination.

Further, an alloy containing these materials may be used. Examples of the alloy used for the gate electrode 12 include an alloy of nickel and phosphorus.

A shape of the gate electrode 12 is not particularly limited, but is preferably a square shape in a plan view which is a channel length direction and a channel width direction of the thin film transistor, from the viewpoint of controllability of the channel length and channel width.

A size of the gate electrode 12 may be any size as long as it can secure the channel length and channel width of the thin film transistor.

Here, the channel length direction of the thin film transistor is a facing direction of the source electrode 15a and the drain electrode 15b of the thin film transistor.

Further, the channel width direction of the thin film transistor is a direction orthogonal to the channel length direction of the thin film transistor and parallel to the surface of the substrate 11.

An average thickness of the gate electrode 12 is, for example, 50 nm or more and 500 nm or less, and 100 nm or more and 400 nm or less.

In order to improve coverage of the gate insulating film 13, a cross section of the gate electrode 12 in a thickness direction may have a tapered shape that expands toward the substrate 11. When the gate electrode 12 has the tapered shape, the taper angle is preferably 30° or more and 40° or less.

<<Gate Insulating Film>>

The gate insulating film 13 is formed on one surface of the substrate 11 so as to cover the gate electrode 12. In the present embodiment, the surface of the substrate 11 on which the gate electrode 12 is formed is referred to as an upper main surface. In the present embodiment, the gate insulating film 13 is a laminated film in which a SiOₓ film and a SiC_{y}N_{z} film are alternately laminated.

The x of the SiOₓ film is preferably 1.7 or more and 2.4 or less, and more preferably 1.9 or more and 2.1 or less.

The y of the SiC_{y}N_{z} film is preferably 1.0 or more and 3.5 or less, and more preferably 1.0 or more and 2.0 or less.

The z of the SiC_{y}N_{z} film is preferably more than 0 and 1.0 or less, and more preferably 0.2 or more and 0.7 or less.

The total number of films constituting the laminated film is 3 or more and 18 or less, preferably 4 or more and 16 or less. In the present embodiment, the total number of films constituting the laminated film may be an odd number or an even number, but more preferably an even number.

When the total number of films constituting the laminated film is an odd number, a layer in contact with the semiconductor film 14 is preferably formed to be the SiOₓ film. That is, the laminated film preferably includes the SiOₓ film, the SiC_{y}N_{z} film, and the SiOₓ film in this order from a side of the substrate 11.

The laminated film preferably has the SiC_{y}N_{z} film and the SiOₓ film which are alternately formed on the gate electrode 12. In addition, the layer in contact with the semiconductor film 14 is preferably formed to be the SiOₓ film.

That is, in a case of the bottom-gate type, the uppermost layer of the laminated film on the semiconductor film 14 side is preferably formed to be the SiOₓ film.

That is, in a case of a top-gate type, the lowermost layer of the laminated film on the semiconductor film 14 side is preferably formed to be the SiOₓ film.

The SiOₓ film has a barrier property against impurities that affect thin film transistor characteristics, such as water (H₂O) and hydrogen (H₂). In the present embodiment, an interface of the SiOₓ film is increased by forming the laminated film with the layer configuration described above. These impurities are trapped at each interface. Therefore, the barrier property is improved, and the impurities are less likely to diffuse to the semiconductor film. As a result, a highly reliable device can be realized. Further, flexibility is imparted because the laminated film has the SiC_{y}N_{z} film, and a device having improved resistance against stress can be obtained.

As a conventional method for forming a SiO₂-based thin film by a plasma CVD apparatus, a method for forming a film at a high temperature of about 200° C. to 300° C. is an exemplary example, from the viewpoint of improved insulating property of the gate insulating film. In addition, a method for essentially performing a post-annealing treatment at a high temperature is an exemplary example.

When a heat treatment at a high temperature is essential as in the conventional method, selectivity of the material of the substrate is lowered, resulting in a problem that a resin substrate cannot be used and the like.

According to the present embodiment, it is possible to obtain a gate insulating film with a high quality at a treatment temperature of, for example, lower than 200° C. by forming a composite insulating film in which the SiC_{y}N_{z} film and the SiOₓ film are alternately formed, without undergoing the heat treatment at a high temperature.

Moreover, by forming the laminated film with the layer configuration described above, it is possible to reduce a stress of the gate insulating film. Therefore, the laminated film can be applied to a flexible substrate that can be repeatedly bent.

The thickness of each film constituting the laminated film is 25 nm or more and 150 nm or less, preferably 26 nm or more and 90 nm or less, and more preferably 27 nm or more and 80 nm or less.

When the thickness of each film constituting the laminated film is the lower limit value or more, a high insulating property can be exhibited. In addition, when the thickness of each film constituting the laminated film is the upper limit value or less, the hysteresis can be made smaller or eliminated, and a highly reliable device can be obtained.

In the present embodiment, the total thickness of the laminated film is preferably 500 nm or less. In addition, the thickness of each film constituting the laminated film is preferably substantially the same. The thickness of each layer may be appropriately adjusted according to the total number of films. In the present embodiment, the thickness of each film constituting the laminated film is preferably substantially the same.

A shape of the gate insulating film 13 is not limited as long as the gate electrode 12 is covered, and for example, the gate insulating film 13 may cover the entire surface of the substrate 11.

The gate insulating film is a laminated film in which SiOₓ films and SiC_{y}N_{z} films are alternately formed, and confirmation can be made by the following method that the total number of films constituting the laminated film is 3 or more and 18 or less, and the thickness of each film constituting the laminated film is 25 nm or more and 150 nm or less.

The concentration of oxygen atoms in each layer constituting the gate insulating film can be measured by composition analysis using Rutherford backscattering spectrometry and hydrogen forward scattering spectrometry. The Rutherford backscattering spectrometry may be abbreviated as “RBS” and the hydrogen forward scattering spectrometry may be abbreviated as “HFS”.

The silicon atom concentration and the carbon atom concentration in each layer constituting the gate insulating film can also be measured by the RBS or HFS.

The concentration of hydrogen atoms, which are impurities present in each layer constituting the gate insulating film, can be measured by the HFS.

In the RBS, an object to be measured is irradiated with high-speed ions (He⁺, H⁺, and the like), and measures the energy and yield of scattered ions for a part of incident ions that are subjected to be elastically scattered (Rutherford scattered) by atomic nuclei of the object to be measured. The energy of scattered ions varies depending on the mass and position (depth) of the target atom. Therefore, an element composition of the object to be measured in the depth direction can be obtained from the energy and yield of the scattered ions.

In the HFS, the object to be measured is irradiated with the high-speed ions (He⁺ and the like) to utilize hydrogen in the object to be measured which is scattered forward by elastic recoil and obtain depth distribution in the element from the energy and yield of the recoiled hydrogen.

The presence of the SiOₓ film can be confirmed by measuring the silicon atom concentration and the oxygen atom concentration by the RBS or HFS. In addition, the presence of the SiC_{y}N_{z} film can be confirmed by measuring the silicon atom concentration, the carbon atom concentration, and a nitrogen atom concentration by the RBS or HFS. By confirming these distributions, it can be confirmed whether or not the laminated film has the SiOₓ film and the SiC_{y}N_{z} film which are alternately formed. In addition, the total number of films constituting the laminated film can be confirmed.

<<Semiconductor Film>>

As a semiconductor material constituting the semiconductor film 14, IGZO (In—Ga—Zn—O-based) having high carrier mobility and relative easiness of film formation, and a transparent amorphous oxide semiconductor (TAOS), zinc oxide (ZnO), nickel oxide (NiO), tin oxide (SnO₂), titanium oxide (TiO₂), vanadium oxide (VO₂), indium oxide (In₂O₃), and strontium titanate (SrTiO₃) can be exemplary examples.

Further, an organic semiconductor may be used as the semiconductor material constituting the semiconductor film 14. As a material of the organic semiconductor, a p-type semiconductor, fullerene, or an n-type semiconductor can be used.

Examples of the p-type semiconductor include copper phthalocyanine (CuPc), pentacene, rubrene, tetracene, and poly(3-hexylthiophene-2,5-diyl (P3HT)).

As the fullerene, C60 is an exemplary example.

As the n-type semiconductor, a perylene derivative such as N,N′-dioctyl-3,4,9,10-perylene terracarboxylic dimide (PTCDI-C8H) is an exemplary example.

Among the semiconductor materials constituting the semiconductor film 14, soluble pentacene and an organic semiconductor polymer are soluble in an organic solvent. Therefore, a semiconductor film can be formed in a wet process. An example of the soluble pentacene includes 6,13-bis(triisopropylsilylethynyl) (TIPS) pentacene.

Examples of the organic semiconductor polymer includes oly(3-hexylthiophene-2,5-diyl) (P3HT) and the like.

Toluene is preferably used as the organic solvent.

<<Source Electrode and Drain Electrode>>

The source electrode 15a and the drain electrode 15b cover a part of the gate insulating film 13, and are electrically connected to the semiconductor film 14 at both ends of a channel of the thin film transistor 1.

A drain current of the thin film transistor 1 flows between the source electrode 15a and the drain electrode 15b according to a voltage between the gate electrode 12 and the source electrode 15a and a voltage between the source electrode 15a and the drain electrode 15b.

A material constituting the source electrode 15a and the drain electrode 15b is not particularly limited as long as it has conductivity, and for example, the same material as the gate electrode 12 can be used.

Examples of an average thickness of the source electrode 15a and the drain electrode 15b include 100 nm or more and 400 nm or less, and 150 nm or more and 300 nm or less.

Examples of a facing distance between the source electrode 15a and the drain electrode 15b, that is, the channel length of the thin film transistor 1 include 5 μm or more and 50 μm or less, and 10 μm or more and 30 μm or less.

Examples of a length in the channel width direction between the source electrode 15a and the drain electrode 15b, that is, the channel width of the thin film transistor 1 is 100 μm or more and 300 μm or less, and 150 μm or more and 250 μm or less.

Although a case of the bottom-gate type thin film transistor has been described as the thin film transistor 1, the top-gate type thin film transistor may be used as another embodiment.

(Characteristics of Thin Film Transistor)

A lower limit of a threshold voltage of the thin film transistor in the present embodiment is preferably −1 V, and more preferably 0 V. On the other hand, an upper limit of the threshold voltage of the thin film transistor is preferably 3 V, and more preferably 2 V.

<Electronic Device>

The present embodiment is an electronic device including the thin film transistor of the present embodiment described above. As the electronic device, a display element such as a liquid crystal display element is an exemplary example.

<Method for Manufacturing Thin Film Transistor>

The present embodiment relates to a method for manufacturing a thin film transistor.

The method for manufacturing a thin film transistor of the present embodiment includes a gate insulating film forming step of alternately forming a SiOₓ film and a SiC_{y}N_{z} film by a plasma CVD method to form a gate insulating film.

In the gate insulating film forming step, a film formation temperature is a temperature of lower than the softening point of the material that constitutes the substrate.

The method for manufacturing a thin film transistor of the present embodiment preferably includes a gate electrode film forming step, a gate insulating film forming step, a semiconductor film forming step, a source and drain electrode-film forming step, and an annealing step in this order.

<Gate Electrode Film Forming Step>

In the gate electrode film forming step, a film of the gate electrode 12 is formed on the surface of the substrate 11.

Specifically, first, a conductive film is formed on the surface of the substrate 11 by a known method, for example, a sputtering method so as to have a desired thickness. Conditions for forming the conductive film by the sputtering method are not particularly limited, but for example, conditions can be set, such as a substrate temperature of 20° C. or higher and 50° C. or lower, a film formation power density of 3 W/cm² or more and 4 W/cm² or less, a pressure of 0.1 Pa or more and 0.4 Pa or less, and a carrier gas of Ar.

Next, the gate electrode 12 is formed by patterning the conductive film. The patterning method is not particularly limited, and for example, a method for performing wet etching after performing photolithography can be used. In this case, it is preferable to etch a cross section of the gate electrode 12 into a tapered shape that expands toward the substrate 11 so as to improve coverage of the gate insulating film 13.

<Gate Insulating Film Forming Step>

In the gate insulating film forming step, the gate insulating film 13 is formed on a surface side of the substrate 11 so as to cover the gate electrode 12.

Specifically, first, a SiC_{y}N_{z} film forming step of forming a SiC_{y}N_{z} film on the substrate 11 and a SiOₓ film forming step of forming a SiOₓ film on the SiC_{y}N_{z} film are performed in this order. By alternately repeating the SiC_{y}N_{z} film forming step and the SiOₓ film forming step, a laminated film in which the SiC_{y}N_{z} film and the SiOₓ film are alternately laminated can be formed.

The SiC_{y}N_{z} film and the SiOₓ film can be formed by a chemical vapor deposition (CVD) method using, for example, a film forming apparatus described in Japanese Patent No. 5967983.

[SiC_{y}N_{z} Film Forming Step]

In the SiC_{y}N_{z} film forming step, a raw material gas is used to form the SiC_{y}N_{z} film on the substrate 11 by the plasma CVD method. As the raw material gas used in the SiC_{y}N_{z} film forming step, a raw material gas composed of an organosilicon compound and a compound containing a hydrogen atom is an exemplary example. Specifically, a raw material gas containing hexamethyldisilazane can be used. Hexamethyldisilazane is abbreviated as “HMDS”.

Specifically, for example, the SiC_{y}N_{z} film is formed by introducing a mixed gas of a hydrogen gas and an argon gas and the raw material gas such as HMDS into a film forming chamber. An example of the introduction speed of the raw material gas is 3 sccm or more and 100 sccm or less.

The mixed gas and the raw material gas are preferably introduced into the film forming chamber at the same time. An example of the introduction speed of the mixed gas is 20 sccm or more and 1,000 sccm or less.

By generating plasma while introducing the mixed gas and the raw material gas, a surface reaction proceeds on the surface of the substrate 11, and the SiC_{y}N_{z} film is formed on the substrate 11.

[SiOₓ Film Forming Step]

In the SiOₓ film forming step, a raw material gas is used to form SiOₓ on the SiC_{y}N_{z} film by the plasma CVD method. As the raw material gas used in the SiOₓ film forming step, a raw material gas composed of an organosilicon compound and a compound containing an oxygen atom is an exemplary example. Specifically, a raw material gas containing hexamethyldisilazane can be used. Hexamethyldisilazane is referred to as “HMDS”.

Specifically, for example, an oxygen gas and the raw material gas such as HMDS are introduced into the film forming chamber to form the SiOₓ film. An example of the introduction speed of the raw material gas is 3 sccm or more and 20 sccm or less.

An example of the introduction speed of the oxygen gas is 20 sccm or more and 1,000 sccm or less.

By generating plasma while introducing the oxygen gas and the raw material gas, a surface reaction proceeds on the surface of the SiC_{y}N_{z} film, and the SiOₓ film is formed on the SiC_{y}N_{z} film.

Before forming the SiC_{y}N_{z} film on the substrate 11, a base film may be formed on the substrate 11 as an optional step. When forming the base film, adhesion between the gate electrode and the SiC_{y}N_{z} film and the substrate and the SiC_{y}N_{z} film can be improved.

In the present embodiment, as the base film that may be formed as an arbitrary step, a film formed by the plasma CVD method and containing at least a silicon atom and an oxygen atom is an exemplary example. The base film preferably has a concentration of oxygen atoms of 10 to 35 element %.

In the present embodiment, the gate insulating film forming step is performed at a temperature lower than the softening point of the material constituting the substrate.

Specifically, a temperature lower than the softening point of the material constituting the substrate by 20° C. or higher is preferable, and a temperature lower than the softening point of the material constituting the substrate by 40° C. or higher lower is more preferable.

In the present embodiment, the composite insulating film in which the SiC_{y}N_{z} film and the SiOₓ film are alternately formed is obtained, and a low-temperature film at a temperature lower than the softening point of the material constituting the substrate can thus be formed.

<Semiconductor Film Forming Step>

In the semiconductor film forming step, the semiconductor film 14 is formed on the surface of the gate insulating film 13 and directly on the gate electrode 12.

Specifically, the semiconductor film 14 is formed by forming a semiconductor layer on the surface of the gate insulating film 13 and then patterning the semiconductor layer.

(Formation of Semiconductor Layer)

Specifically, first, a semiconductor layer is formed on the surface of the gate insulating film 13 by the sputtering method using, for example, a known sputtering apparatus. The semiconductor layer having excellent in-plane uniformity of its components or thickness can be easily formed using the sputtering method.

As a sputtering target used in the sputtering method, an oxide target (IGZO target) containing In, Ga, and Zn can be an exemplary example.

Conditions for forming the semiconductor layer by the sputtering method are not particularly limited, but for example, conditions can be set, such as a substrate temperature of 20° C. or higher and 50° C. or lower, a film formation power density of 2 W/cm² or more and 3 W/cm² or less, a pressure of 0.1 Pa or more and 0.3 Pa or less, and a carrier gas of Ar. Further, it is preferable to contain oxygen in the atmosphere as an oxygen source. A content of oxygen in the atmosphere can be 3 vol % or more and 5 vol % or less.

The method for forming the semiconductor layer is not limited to the sputtering method, and a chemical film forming method such as a coating method may be used.

(Patterning)

Next, the semiconductor film 14 is formed by patterning the semiconductor layer. The method for patterning a semiconductor layer is not particularly limited, and for example, a method for performing wet etching after performing photolithography can be used.

<Source and Drain Electrode Film Forming Step>

In the source and drain electrode film forming step, the source electrode 15a and the drain electrode 15b that are electrically connected to the semiconductor film 14 are formed at both ends of the channel of the thin film transistor.

Specifically, first, a conductive film is formed on the surface of the substrate 11 by a known method, for example, a sputtering method so as to have a desired thickness. Conditions for forming the conductive film by the sputtering method are not particularly limited, but for example, conditions can be set, such as a substrate temperature of 20° C. or higher and 50° C. or lower, a film formation power density of 3 W/cm² or more and 4 W/cm² or less, a pressure of 0.1 Pa or more and 0.4 Pa or less, and a carrier gas of Ar.

Next, the source electrode 15a and the drain electrode 15b are formed by patterning the conductive film. The patterning method is not particularly limited, and for example, a method for performing wet etching after performing photolithography can be used.

<Annealing Step>

The method for manufacturing a thin film transistor preferably further includes an annealing step of annealing at 300° C. or lower after forming the gate insulating film.

The annealing temperature is more preferably 200° C. or lower.

The annealing step is preferably performed for 10 minutes or longer and 8 hours or shorter at the temperature described above.

### EXAMPLES

Hereinafter, the present invention will be specifically described with reference to Examples, but the present invention is not limited to the following Examples.

### Example 1

[Gate Electrode Film Forming Step]

A polyimide film having a thickness of 125 μm (softening point: 290° C.) was used as a substrate 11. A metal mask (SUS430 having a thickness of 0.08 mm) having a pattern corresponding to the gate electrode was placed on one surface of the cleaned substrate 11, and a conductive film (Al film: 50 nm), which was a material for forming a gate electrode 12, was formed by a resistance heating vacuum deposition method. As a result, the gate electrode 12 was formed on the substrate 11.

[Gate Insulating Film Forming Step]

Next, a gate insulating film 13 was formed on the entire upper main surface of the substrate 11 so as to cover the gate electrode 12. The gate insulating film 13 had a SiOₓ film and a SiC_{y}N_{z} film which are alternately formed by the following steps using a chemical vapor deposition (CVD) method.

[Gate Insulating Film Forming Step]

In a gate insulating film forming step, the gate insulating film 13 was formed on a surface side of the substrate 11 so as to cover the gate electrode 12.

The SiC_{y}N_{z} film and the SiOₓ film were formed by the chemical vapor deposition (CVD) method using a film forming apparatus described in Japanese Patent No. 5967983.

[SiC_{y}N_{z} Film Forming Step]

A raw material gas was used to form the SiC_{y}N_{z} film on the substrate 11 by a plasma CVD method. In a SiC_{y}N_{z} film forming step, a HMDS gas was used as the raw material gas.

A mixed gas of a hydrogen gas and an argon gas and the HMDS gas were introduced into a film forming chamber to form the SiC_{y}N_{z} film. An introduction speed of the raw material gas was 3 to 100 sccm.

The mixed gas and the raw material gas were introduced into the film forming chamber at the same time. An introduction speed of the mixed gas was 20 to 1,000 sccm.

The SiC_{y}N_{z} film was formed on the substrate 11 by generating plasma while introducing the mixed gas and the raw material gas. The plasma was generated with a plasma power of 1 to 20 kW until the SiC_{y}N_{z} film had a predetermined thickness.

[SiOₓ Film Forming Step]

The raw material gas was used to form the SiOₓ film on the SiC_{y}N_{z} film by the plasma CVD method. In the SiOₓ film forming step, the HMDS gas was used as the raw material gas.

An oxygen gas and the HMDS gas were introduced into the film forming chamber to form the SiOₓ film. An introduction speed of the HMDS gas was 10 to 100 sccm.

An introduction speed of the oxygen gas was 20 to 1,000 sccm.

The SiOₓ film was formed on the SiC_{y}N_{z} film by generating plasma while introducing the oxygen gas and the raw material gas. The plasma was generated with a plasma power of 1 to 20 kW until the SiOₓ film had a predetermined thickness.

A film formation temperature in the gate insulating film forming step was 82° C.

In Example 1, one set of the SiC_{y}N_{z} film forming step and the SiOₓ film forming step was counted as one time, and was performed twice to form a four-layered gate insulating film. Here, one time of performing the SiC_{y}N_{z} film forming step and the SiOₓ film forming step was counted as one time.

When the four-layered gate insulating film 13 manufactured in Example 1 was analyzed by RBS or HFS, it was found that y was 1.0 or more and 2.0 or less and z was 0.2 or more and 0.7 in the formed SiC_{y}N_{z} film. In the formed SiOₓ film, x was 1.9 or more and 2.1 or less.

When the four-layered gate insulating film 13 manufactured in Example 1 was analyzed by the RBS or HFS, it was found that it is configured in four layers of a SiC_{y}N_{z} film having a thickness of 100 nm, a SiOₓ film having a thickness of 100 nm, a SiC_{y}N_{z} film having a thickness of 100 nm, and a SiOₓ film having a thickness of 100 nm, from the side of the gate electrode 12.

[Semiconductor Film Forming Step]

Next, a semiconductor film 14 was formed on the gate insulating film 13.

An oxide semiconductor film, which was the material for forming the semiconductor film 14, was formed by a sputtering method using an InGaZNO target [In₂O₃.Ga₂O₃.(ZnO)₂] which has an atomic composition ratio In:Ga:Zn of 2:2:1. The semiconductor film 14 was patterned using a metal mask in the same manner as the gate electrode 12.

As a result, an InGaZnO film having a thickness of 20 nm was formed.

[Source Electrode and Drain Electrode Film Forming Step]

Next, a conductive film (Al film: 50 nm), which was a material of a source electrode 15a and a drain electrode 15b, was formed by the resistance heating vacuum deposition method. The film formation of the source electrode and the drain electrode was performed via the metal mask to obtain the source electrode 15a and the drain electrode 15b having a desired pattern shape.

The source electrode 15a and the drain electrode 15b were each formed to overlap the gate insulating film 13 and the semiconductor film 14.

A part of the semiconductor film 14 was formed to be exposed between the source electrode 15a and the drain electrode 15b.

[Annealing Step]

After forming the gate insulating film, an annealing step was further performed at 105° C. or lower for 8 hours. As a result, a thin film transistor of Example 1 was obtained.

### Example 2

A thin film transistor was manufactured in the same manner as in Example 1, except that one set of the SiC_{y}N_{z} film forming step and the SiOₓ film forming step was counted as one time, and performed four times, thereby forming, from the side of the gate electrode 12, an eight-layered gate insulating film 13 of a SiC_{y}N_{z} film having a thickness of 50 nm, a SiOₓ film having a thickness of 50 nm, a SiC_{y}N_{z} film having a thickness of 50 nm, a SiOₓ film having a thickness of 50 nm, a SiC_{y}N_{z} film having a thickness of 50 nm, a SiOₓ film having a thickness of 50 nm, a SiC_{y}N_{z} film having a thickness of 50 nm, and a SiOₓ film having a thickness of 50 nm.

### Example 3

A thin film transistor was manufactured in the same manner as in Example 1, except that one set of the SiC_{y}N_{z} film forming step and the SiOₓ film forming step was counted as one time, and performed seven times, thereby forming a fourteen-layered gate insulating film 13 obtained by alternately forming, from the side of the gate electrode 12, SiC_{y}N_{z} films having a thickness of 30 nm and SiOₓ films having a thickness of 30 nm in this order.

### Example 4

A thin film transistor was manufactured in the same manner as in Example 1, except that the SiOₓ film forming step, the SiC_{y}N_{z} film forming step, and the SiOₓ film forming step were performed in this order, thereby forming a three-layered gate insulating film 13 of a SiOₓ film having a thickness of 50 nm, a SiC_{y}N_{z} film having a thickness of 300 nm, and a SiOₓ film having a thickness of 50 nm, from the side of the gate electrode 12.

### Comparative Example 1

A thin film transistor was manufactured in the same manner as in Example 1, except that the gate insulating film 13, which was a SiC_{y}N_{z} film having a thickness of 400 nm, was formed.

### Comparative Example 2

A thin film transistor was manufactured in the same manner as in Example 1, except that one set of the SiC_{y}N_{z} film forming step and the SiOₓ film forming step was counted as one time, and performed ten times, thereby forming a twenty-layered gate insulating film 13 obtained by alternately forming, from the side of the gate electrode 12, SiC_{y}N_{z} films having a thickness of 20 nm and SiOₓ films having a thickness of 20 nm in this order.

<Evaluation of Thin Film Transistor Characteristics>

Characteristics of the thin film transistors manufactured in Examples 1 to 4 and Comparative Examples 1 and 2 were evaluated.

The thin film transistors manufactured in Examples 1 to 4 and Comparative Examples 1 and 2 were evaluated for a transistor performance using a semiconductor parameter analyzer (4200A-SCS, manufactured by Keithley).

A voltage Vds between the source and drain electrodes was set to 10 V, and a gate voltage was changed from Vg=−10 V to +20 V to evaluate current-voltage characteristics (transmission characteristics).

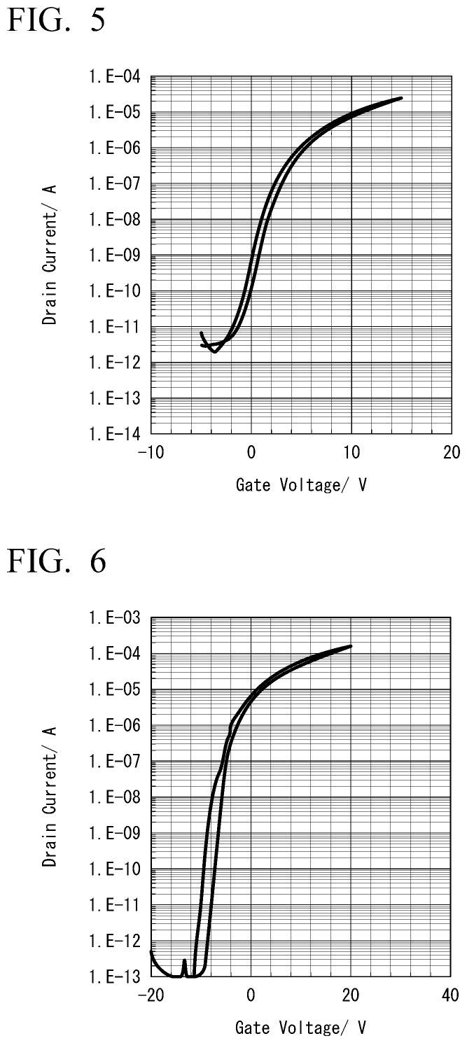

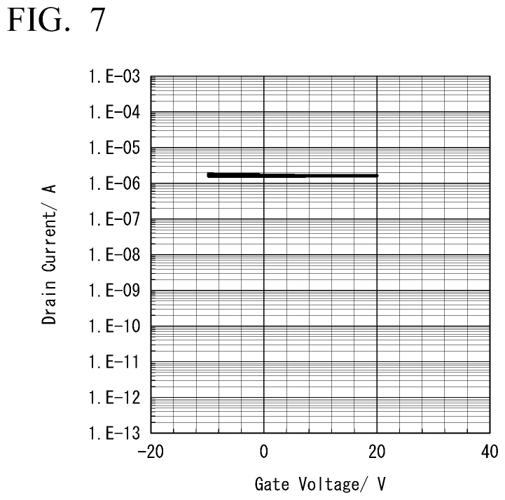

The results thereof are shown in FIGS. 2 to 7, and the results of Examples 1 to 4 are each shown in FIGS. 2 to 5. The results of Comparative Examples 1 and 2 are each shown in FIGS. 6 and 7.

In FIGS. 2 to 7, a vertical axis represents the drain current, and a horizontal axis represents the gate voltage.

In Examples 1 to 4 shown in FIGS. 2 to 5, a lower limit value of the threshold voltage was near 0 V, and negative shift of the threshold voltage was suppressed. Further, in Examples 1 to 4 shown in FIGS. 2 to 5, good thin film transistor characteristics with small hysteresis were obtained.

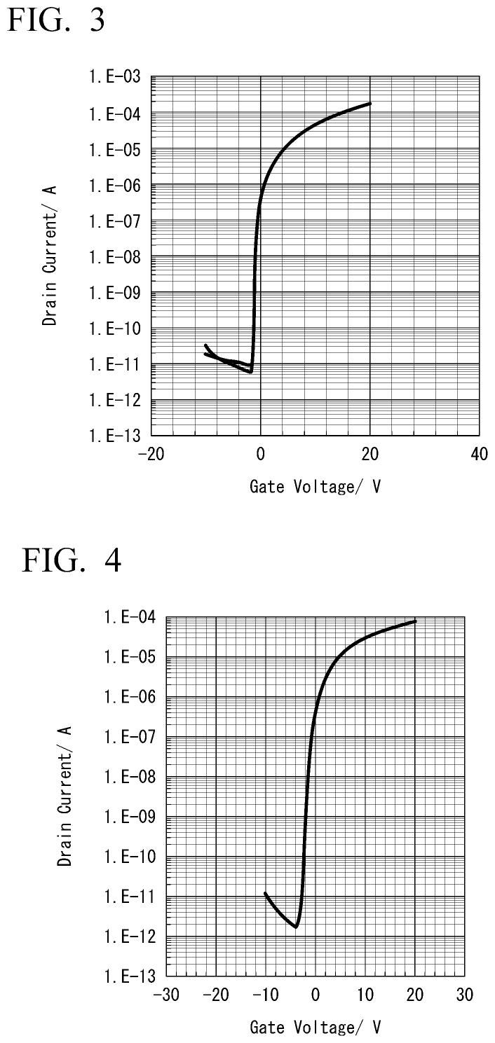

Among them, it was confirmed that in Example 2 shown in FIG. 3 and Example 3 shown in FIG. 4, hysteresis did not occur and reliability of the initial characteristics was enhanced.

On the other hand, in Comparative Example 1, the lower limit value of the threshold voltage was shifted to the minus side, as shown in FIG. 6. Further, Comparative Example 2 shown in FIG. 7 had a malfunction. It is considered that this is because the thickness of each layer constituting the gate insulating film was too thin.

### REFERENCE SIGNS LIST

1: Thin film transistor
11: Substrate
12: Gate electrode
13: Gate insulating film
14: Semiconductor film (oxide semiconductor)
15a: Source electrode
15b: Drain electrode

1. A transistor comprising:
a gate electrode;
a gate insulating film;
a semiconductor film;
a source electrode; and
a drain electrode,
wherein the gate insulating film is a laminated film in which a SiOx film and a SiCyNz film are alternately formed,
a total number of films constituting the laminated film is 3 or more and 18 or less, and
a thickness of each film constituting the laminated film is 25 nm or more and 150 nm or less.

2. The transistor according to claim 1,
wherein x in the SiOx film is 1.7 or more and 2.4 or less.

3. The transistor according to claim 1,
wherein y in the SiCyNz film is 1.0 or more and 3.5 or less, and z is more than 0 and 1.0 or less.

4. The transistor according to claim 1,
wherein a total thickness of the laminated film is 500 nm or less.

5. The transistor according to claim 1,
wherein in the laminated film, a layer that is in contact with the semiconductor film is the SiOx film.

6. The transistor according to claim 1,
wherein a thickness of each film constituting the laminated film is substantially the same.

7. The transistor according to claim 1,
wherein the transistor is formed on a flexible substrate.

8. The transistor according to claim 1,
wherein the transistor is formed on a substrate made of a resin material.

9. An electronic device comprising the transistor according to claim 1.

10. A method for manufacturing the transistor according to claim 1, the method comprising:
a gate insulating film forming step of alternately forming the SiOx film and the SiCyNz film by a plasma CVD method to form the gate insulating film,
wherein in the gate insulating film forming step, a film formation temperature is a temperature lower than a softening point of a material constituting a substrate.

11. The method for manufacturing the transistor according to claim 10, further comprising:
an annealing step of performing annealing at the temperature lower than the softening point after the gate insulating film forming step.

12. The transistor according to claim 2,
wherein y in the SiCyNz film is 1.0 or more and 3.5 or less, and z is more than 0 and 1.0 or less.

13. The transistor according to claim 2,
wherein a total thickness of the laminated film is 500 nm or less.

14. The transistor according to claim 2,
wherein in the laminated film, a layer that is in contact with the semiconductor film is the SiOx film.

15. The transistor according to claim 2,
wherein a thickness of each film constituting the laminated film is substantially the same.

16. The transistor according to claim 2,
wherein the transistor is formed on a flexible substrate.

17. The transistor according to claim 2,
wherein the transistor is formed on a substrate made of a resin material.

18. An electronic device comprising the transistor according to claim 2.

19. A method for manufacturing the transistor according to claim 2, the method comprising:
a gate insulating film forming step of alternately forming the SiOx film and the SiCyNz film by a plasma CVD method to form the gate insulating film,
wherein in the gate insulating film forming step, a film formation temperature is a temperature lower than a softening point of a material constituting a substrate.

20. The method for manufacturing the transistor according to claim 19, further comprising:
an annealing step of performing annealing at the temperature lower than the softening point after the gate insulating film forming step.
